(19) United States
(12) Patent Application Publication
(10) Pub. No.: US 2020/0075364 A1
(43) Pub. Date: Mar. 5, 2020

(54) GLUE DISPENSING APPARATUS

(71) Applicant: Ke Huang Corporation, Hsinchu County (TW)

(72) Inventor: Shiann-Tsong Tsai, Hsinchu City (TW)

(21) Appl. No.: 16/192,823

(22) Filed: Nov. 16, 2018

(30) Foreign Application Priority Data
Sep. 5, 2018 (TW) 107131088
Oct. 23, 2018 (CN) 201811239079.8

(51) Int. Cl. H01L 21/67; B05C 5/00; H01L 21/677

(52) U.S. Cl. CPC H01L 21/67144; H01L 23/49513; H01L 21/67721; B05C 5/002

(57) ABSTRACT

The glue dispensing apparatus of the present invention includes a conveying device; at least one substrate moved along a predetermined direction by the conveying device; a dispensing stage located under the conveying device; and an anti-stain device coupled to the dispensing stage for providing isolation paper between the substrate and the dispensing stage. The substrate is a leadframe-type substrate. The glue dispensing apparatus further includes a glue dispensing nozzle positioned above the conveying device for applying a fluid glue material onto the substrate.

### CROSS REFERENCE TO RELATED APPLICATION

This application claims the benefit of Taiwan patent application No. 107131088, filed on Sep. 5, 2018 and the benefit of CN application No. 201811239079.8, filed on Oct. 23, 2018, the disclosures of which are incorporated herein in their entirety by reference.

### BACKGROUND OF THE INVENTION

### 1. Field of the Invention

The invention relates to the technical field of semiconductor back-end packaging processes. In particular, the invention relates to a glue dispensing apparatus, which can avoid the contamination problem caused by the residual glue on the dispensing stage.

### 2. Description of the Prior Art

In the semiconductor back-end packaging processes, after the bonding wires between a chip and a substrate are formed, a sealing process or an encapsulation process is further performed, and the chip and the substrate are sealed within a resin molding compound to protect the chip from the external environmental stresses.

However, during the sealing process, problems such as mold wire sweep, abnormal open circuit and/or short circuit caused by the stress of the resin molding compound may occur, which result in low yield. Therefore, a glue dispensing process is usually introduced between the wire bonding process and the sealing process. The glue is applied onto the bonding wires. After the glue is cured, the sealing process is performed.

The prior art glue dispensing apparatus has some drawbacks. For example, when applying glue onto a leadframe-type substrate, residual glue may be found on the dispensing stage, which may contaminate the subsequent substrates to be processed. Therefore, there is still a need in the art for an improved glue dispensing apparatus to address the deficiencies of the prior art described above.

### SUMMARY OF THE INVENTION

One object of the present invention is to provide an improved glue dispensing apparatus that avoids contamination problems caused by residual glue on the dispensing stage.

According to one embodiment of the invention, a glue dispensing apparatus includes a conveying device, at least one substrate moved along a predetermined direction by the conveying device, a dispensing stage located under the conveying device, and an anti-stain device coupled to the dispensing stage for providing isolation paper between the substrate and the dispensing stage. According to one embodiment of the invention, the substrate is a leadframe-type substrate. The glue dispensing apparatus further includes a glue dispensing nozzle positioned above the conveying device for applying a fluid glue material onto the substrate. For example, the isolation paper is a dust-free paper.

According to one embodiment of the invention, the conveying device comprises a pair of parallel rails with a gap between the two parallel rails, so that only opposite side edges of the substrate are in direct contact with the pair of parallel rails, and a middle portion of the substrate is suspended. The dispensing stage is raised to support the substrate through the gap, and the substrate is lifted and disengaged from contact with the pair of parallel rails, wherein the substrate is fixed with a retention member above the substrate to facilitate positioning.

According to one embodiment of the invention, the anti-stain device comprises an isolation paper storage and delivery unit coupled to one side of the dispensing stage, and the isolation paper is placed in the isolation paper storage and delivery unit, wherein the isolation paper is delivered to an upper surface of the dispensing storage through a roller and a guiding mechanism. A transition connection platform is disposed between the isolation paper storage and delivery unit and the dispensing storage, so that the isolation paper is smoothly fed to the upper surface of the dispensing storage without jamming. The anti-stain device further comprises a displacement unit for removing the isolation paper from the upper surface of the dispensing storage.

According to another embodiment of the invention, the anti-stain device comprises a first roller, on which a roll of isolation paper is installed, and a second roller connected to one end of the roll of isolation paper. The first roller and the second roller are operated at the same rotational speed and the same rotational direction, so that the isolation paper is rolled in a predetermined direction. When dispensing process is performed, the dispensing storage first lifts the isolation paper between the first roller and the second roller, and then lifts the substrate. Since the upper surface of the dispensing storage is covered by the isolation paper, the anti-stain effect can be achieved.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIG. 1 is a schematic view of a glue dispensing apparatus according to an embodiment of the invention;

FIG. 2 is a schematic view of a glue dispensing apparatus according to another embodiment of the present invention;

FIG. 3 is a schematic view of a glue dispensing apparatus according to still another embodiment of the present invention; and

FIG. 4 is a schematic, perspective view showing the substrate under glue dispensing treatment.

### DETAILED DESCRIPTION

The technical solutions in the embodiments of the present invention are clearly and completely described in the following description with reference to the accompanying drawings. It is obvious that the described embodiments are only a part of the embodiments of the present invention, and not all embodiments. All other embodiments obtained by those skilled in the art based on the embodiments of the present invention without creative efforts are within the scope of the present invention.

It should be noted that if there is a directional indication (such as up, down, left, right, front, back, . . . ) in the embodiment of the present invention, the directional indication is only used to explain in a certain posture (as shown in the drawing) The relative positional relationship between the components, the motion situation, and the like, if the specific posture changes, the directional indication also changes accordingly.

In addition, if there is a description of “first”, “second”, etc. in the embodiments of the present invention, the description of the “first”, “second”, etc. is used for the purpose of description only, and is not to be construed as its relative importance or implicit indication of the number of technical features indicated. Thus, features defining “first” or “second” may include at least one of the features, either explicitly or implicitly. In addition, the meaning of “and/or” appearing throughout the text includes three parallel schemes, taking “A and/or B” as an example, including the A scheme, or the B scheme, or the scheme in which both A and B are simultaneously satisfied. In addition, the technical solutions of the various embodiments may be combined with each other, but must be based on the realization of those skilled in the art, and when the combination of the technical solutions is contradictory or impossible to implement, it should be considered that the combination of the technical solutions does not exist and therefore not within the scope of the present invention.

The invention discloses an automatic glue dispensing apparatus and system for semiconductor back-end packaging processes, which is particularly suitable for a leadframe-type substrate, which can effectively avoid residual glue on the dispensing stage and the potential contamination of the next substrate.

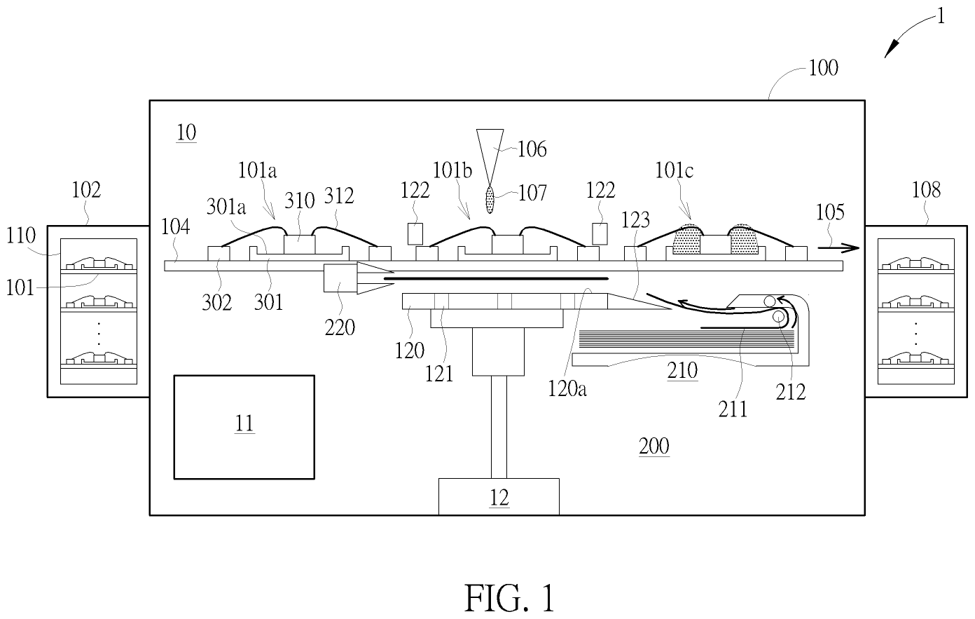

FIG. 1 is a schematic, cross-sectional diagram showing a glue dispensing apparatus according to an embodiment of the invention. As shown in FIG. 1, the glue dispensing apparatus 1 of the present invention comprises an apparatus body 100, which defines a sealed application space 10. According to an embodiment of the invention, the glue dispensing process is performed in the application space 10 of the apparatus body 100, but is not limited thereto. According to an embodiment of the invention, the glue dispensing process refers hereinafter to a glue dispensing process between a wire bonding process and a sealing (or encapsulation) process of the semiconductor back-end packaging process, but is not limited thereto.

According to an embodiment of the present invention, the glue dispensing apparatus 1 may comprise a loading station (or module) 102 coupled to the apparatus body 100. A magazine 110 for holding or containing a plurality of workpieces or substrates 101 to be processed is loaded into the loading station 102. A substrate 101 is then transferred to a conveying device, such as the rail conveyor 104, by a gripper arm or a loading robot (not shown). The substrate 101 is horizontally conveyed and moved along a predetermined direction 105 on the rail conveyor 104. After dispensing the glue, the substrate 101 is moved to an unloading station 108 and the substrate 101 is ready to proceed to the next processing step, such as curing or sealing.

According to an embodiment of the present invention, the substrate 101 may be a leadframe-type substrate, but is not limited thereto. For example, the leadframe-type substrate 101 may include, but is not limited to, a die pad 301 for supporting a chip or die 310, leads 302, and bonding wires 312 for connecting the leads 302 and the die 310. The die pad 301 may include a recessed structure, but is not limited thereto. According to an embodiment of the present invention, the surface 301a of the die pad 301 may also be subjected to surface roughening treatment so that the subsequently applied glue may be more closely bonded to the substrate 101.

In FIG. 1, for the sake of simplicity, only three leadframe-type substrates 101a-101c are illustrated on the rail conveyor 104, in which the substrate 101c has been subjected to the glue dispensing process, the substrate 101b is being processed for glue dispensing, and the substrate 101a has not yet been processed. According to an embodiment of the invention, the rail conveyor 104 may comprise a pair of parallel rails with a gap between the two parallel rails, so that only opposite side edges of each of the substrates 101a-101c are in direct contact with the rail conveyor 104, and the middle portion of each of the substrates 101a-101c may be suspended.

When the substrate 101b to be subjected to the glue dispensing process reaches a predetermined position, the dispensing stage 120 located directly below the substrate 101b will be raised by the lift mechanism 12 through the gap of the rail conveyor 104 and the substrate 101b is supported by the dispensing stage 120. The substrate 101b is slightly lifted and disengaged from the contact with the rail conveyor 104. The substrate 101b is fixed with a retention member 122 disposed above the substrate 100 to facilitate mechanical and/or visual positioning.

After the substrate 101b is fixed, the glue dispensing nozzle 106 located above the substrate 101b and the rail conveyor 104 can apply a fluid glue material 107, such as a resin or UV glue, to a predetermined position on the substrate 101b, for example, within the recessed structure of the die pad 301. A portion of each of the bonding wires 312 can be covered with fluid glue material 107. Due to the hollow areas between the die pad 301 and the leads 302, when the glue dispensing nozzle 106 sprays the resin onto the substrate 101b, it is likely to splash onto the upper surface 120a of the dispensing stage 120 below, thereby contaminating the next substrate. 101a.

In order to solve such a problem, the glue dispensing apparatus 1 of the present invention further includes an anti-stain device 200 including an isolation paper storage and delivery unit 210 coupled to one side of the dispensing stage 120. A pile of isolation paper 211 is stored in the isolation paper storage and delivery unit 210 and is fed to the upper surface 120a of the dispensing stage 120 in a sheet-by-sheet manner through the rollers 212 and the guiding mechanism in the isolation paper storage and delivery unit 210 at a set time interval controlled by a control computer 11. A transition connection platform 123 is provided between a side of the dispensing stage 120 and the isolation paper storage and delivery unit 210 so that the isolation paper 211 can be smoothly slid to the upper surface 120a of the dispensing stage 120 without jamming.

According to an embodiment of the invention, the isolation paper 211 may be the dust-free paper for isolating the stacked substrates used at a front end or a previous processing station. Originally, the used dust-free paper was discarded after the substrates are taken out and placed into the magazine 110. However, in the present invention, the dust-free paper can be recycled and reused to achieve process improvement and cost reduction.

According to an embodiment of the present invention, the dispensing stage 120 may be provided with a plurality of vacuum holes 121. After the isolation paper 211 is fed to the upper surface 120a of the dispensing stage 120, the isolation paper 211 may be sucked by vacuuming through the vacuum holes 121 and fixed on the upper surface 120a of the dispensing stage 120. The dispensing stage 120 directly below the substrate 101b is then raised through the gap in the middle of the rail conveyor 104 and slightly lifts the substrate 101b out of contact with the rail conveyor 104. The substrate 101b may be fixed by the retention member 122 above the substrate 101b for positioning purposes.

After the substrate 101b is fixed, the glue dispensing nozzle 106 located above the substrate 101b can apply a fluid glue material 107, such as a resin or UV glue, to a predetermined position on the substrate 101b, for example, a recessed structure of the die pad 301. The fluid glue material 107 may cover a portion of each of the bonding wire 312. Since the bottom of the substrate 101b only contacts the isolation paper 211, the splashed glue does not contact the upper surface 120a of the underlying dispensing stage 120, thus achieving the anti-stain effect.

After the substrate 101b is finished with the dispensing process, the dispensing stage 120 descends, and the substrate 101b is again in contact with the rail conveyor 104. Since the isolation paper 211 on the upper surface 120a of the dispensing stage 120 is still sucked by vacuum, it also descends with the dispensing stage 120. After the vacuum is removed, the contaminated isolation paper 211 is removed from the upper surface 120a of the dispensing stage 120 by a displacement unit 220. The removed isolation paper 211 may be placed in a recovery area. According to an embodiment of the invention, the displacement unit 220 may be a gripper jaw device or a robot gripper arm, but is not limited thereto. Subsequently, a new isolation paper 211 is fed to the upper surface 120a of the dispensing stage 120 by the isolation paper storage and delivery unit 210, and then the glue dispensing process of the next substrate 101a is performed in a manner described above.

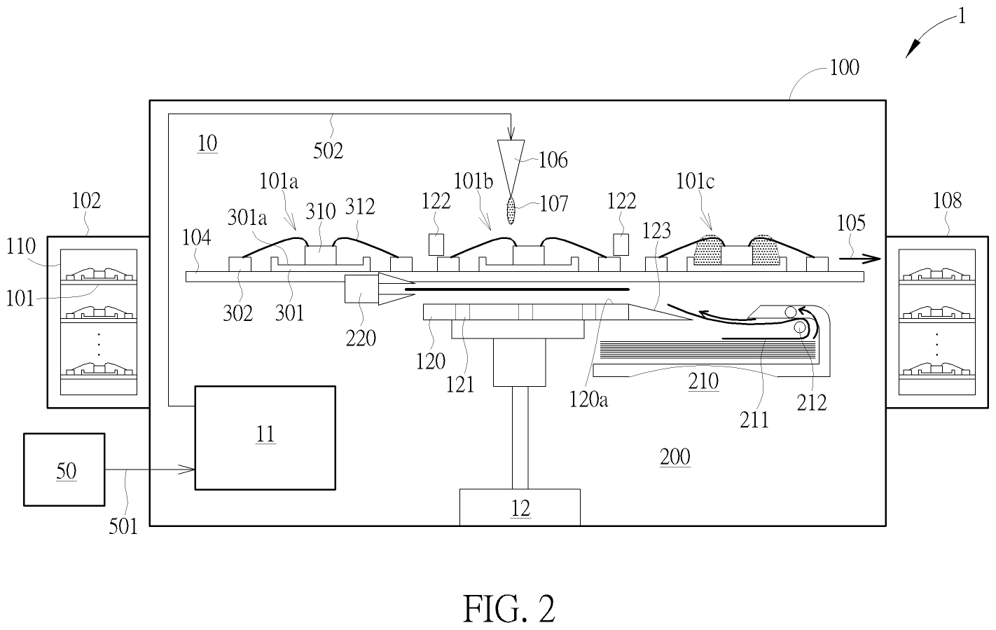

FIG. 2 is a schematic view of a glue dispensing apparatus according to another embodiment of the present invention, wherein like reference numerals designate like regions, elements or materials. As shown in FIG. 2, the glue dispensing device 1 of the present invention can be further connected to a previous processing tool 50 in a real-time manner. For example, the previous processing tool 50 may be a wire bonder, but is not limited thereto. For example, the previous processing tool 50 may be a wire bonder manufactured by K&S (Kulicke & Soffa (NASDAQ: KLIC)), but is not limited thereto. For example, the bonding wires 312 of the substrates 101a-101c are completed in the wire bonded, but is not limited thereto.

According to an embodiment of the present invention, after the bonding wires 312 of the substrates 101a-101c are completed in the previous processing tool 50, the process parameters 501 of the batch of the substrates 101a-101c, including, but not limited to, layout and/or loop height of the bonding wires 312 or the like may be recorded in time and transmitted to the control computer 11 of the glue dispensing apparatus 1. When the batch of the substrate 101a-101c enters the glue dispensing apparatus 1 for glue dispensing, the control computer 11 of the glue dispensing apparatus 1 outputs a control signal 502 according to the process parameters 501 transmitted from the previous processing tool 50 to the glue dispensing nozzle 106, thereby precisely control the route, height and/or position of the glue dispensing nozzle 106.

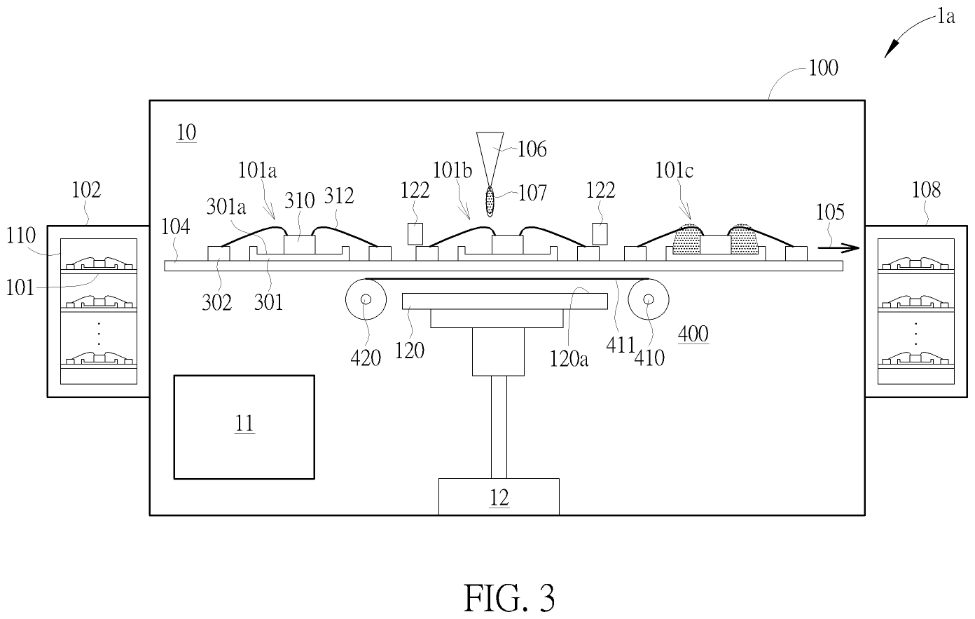

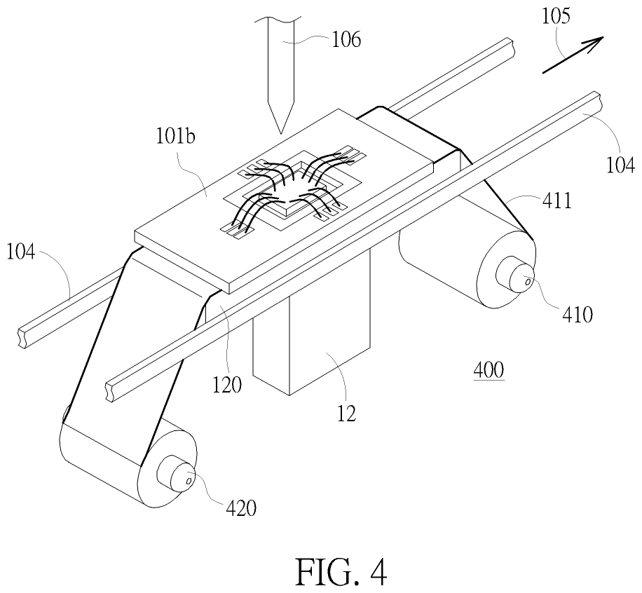

Please refer to FIG. 3 and FIG. 4. FIG. 3 is a schematic view of a glue dispensing apparatus according to still another embodiment of the present invention, wherein like reference numerals designate like regions, elements or materials. FIG. 4 is a schematic, perspective view showing the substrate under glue dispensing treatment. As shown in FIG. 3, likewise, the glue dispensing apparatus 1a comprises an apparatus body 100, which defines a sealed application space 10. According to an embodiment of the invention, the glue dispensing process may be performed in the application space 10 of the apparatus body 100, but is not limited thereto. According to an embodiment of the invention, the glue dispensing process refers to a glue dispensing process between a wire bonding process and a sealing (or encapsulation) process of the semiconductor back-end packaging process, but is not limited thereto.

According to an embodiment of the present invention, the glue dispensing apparatus 1a may comprise a loading station 102 coupled to the apparatus body 100. A magazine 110 for holding or containing a plurality of workpieces or substrates 101 to be processed is loaded into the loading station 102. A substrate 101 is then transferred to a conveying device, such as the rail conveyor 104, by a gripper arm or a loading robot (not shown). The substrate 101 is horizontally conveyed and moved along a predetermined direction 105 on the rail conveyor 104. After dispensing the glue, the substrate 101 is moved to an unloading station 108 and the substrate 101 is ready to proceed to the next processing step, such as curing or sealing.

According to an embodiment of the present invention, the substrate 101 may be a leadframe-type substrate, but is not limited thereto. For example, the leadframe-type substrate 101 may include, but is not limited to, a die pad 301 for supporting a chip or die 310, leads 302, and bonding wires 312 for connecting the leads 302 to the die 310. The die pad 301 may include a recessed structure, but is not limited thereto. According to an embodiment of the present invention, the surface 301a of the die pad 301 may also be subjected to surface roughening treatment so that the subsequently applied glue may be more closely bonded to the substrate 101.

In FIG. 3, for the sake of simplicity, only three leadframe-type substrates 101a-101c are illustrated on the rail conveyor 104, in which the substrate 101c has been subjected to the glue dispensing process, the substrate 101b is being processed for glue dispensing, and the substrate 101a has not yet been processed. According to an embodiment of the invention, the rail conveyor 104 may comprise a pair of parallel rails with a gap between the two parallel rails, so that only opposite side edges of each of the substrates 101a-101c are in direct contact with the rail conveyor 104, and the middle portion of each of the substrates 101a-101c may be suspended.

According to an embodiment of the present invention, the glue dispensing apparatus 1a further comprises an anti-stain device 400, including a first roller 410, on which a roll of the isolation paper 411 is installed, and a second roller 420. One end of the isolation paper 411 is connected to the second roller 420, so that the isolation paper 411 is located between the substrate 101b and the dispensing stage 120. According to an embodiment of the invention, the first roller 410 and the second roller 420 may be coupled to a motor (not shown). The first roller 410 and the second roller 420 are operated at the same rotational speed and the same rotational direction (for example, both rotating in a clockwise or counterclockwise direction) as controlled by the control computer 11, so that the isolation paper 411 can be rolled in a predetermined direction.

As shown in FIG. 3 and FIG. 4, when the substrate 101b to be subjected to the glue dispensing process reaches a predetermined position, the dispensing stage 120 located directly below the substrate 101b will be lifted by the lifting mechanism 12, through the gap of the rail conveyor 104 and the substrate 101b is supported by the dispensing stage 120. The substrate 101b is slightly lifted and disengaged from the contact with the rail conveyor 104. The substrate 101b is fixed with a retention member 122 disposed above the substrate 100 to facilitate mechanical and/or visual positioning. At this point, the first roller 410 and the second roller 420 are temporarily not rotated, and the dispensing stage 120 first lifts the isolation paper 411 between the first roller 410 and the second roller 420, and then lifts the substrate 101b.

After the substrate 101b is fixed, the glue dispensing nozzle 106 located above the substrate 101b can apply a fluid glue material 107, such as a resin or UV glue, to a predetermined position on the substrate 101b, for example, a recessed structure of the die pad 301. The fluid glue material 107 may cover a portion of each of the bonding wire 312. Since the bottom of the substrate 101b only contacts the isolation paper 211, the splashed glue does not contact the upper surface 120a of the underlying dispensing stage 120, thus achieving the anti-stain effect.

After the substrate 101b is finished with the dispensing process, the dispensing stage 120 descends, and the substrate 101b is again in contact with the rail conveyor 104. The contaminated portion of the isolation paper 411 is removed from the upper surface 120a of the dispensing stage 120 by the first roller 410 and the second roller 420 operated at the same rotational speed and the same rotational direction set by the control computer 11. A clean portion of the isolation paper 411 is moved to the upper surface 120a of the dispensing stage 120, and then the glue dispensing process of the next substrate 101a is performed.

As explained in the above detailed description, the glue dispensing apparatus of the present invention comprises a conveying device. At least one substrate is moved along a predetermined direction by the conveying device. A dispensing stage is located below the conveying device. An anti-stain device is coupled to the dispensing stage to provide an isolation paper between the substrate and the dispensing stage. According to an embodiment of the invention, the substrate is a leadframe-type substrate. The glue dispensing apparatus further comprises a glue dispensing nozzle positioned above the conveying device for applying a fluid glue material to the substrate. For example, the isolation paper is a dust-free paper.

According to an embodiment of the invention, the conveying device comprises a pair of parallel rails with a gap between the two parallel rails, so that only opposite side edges of the substrate are in direct contact with the pair of parallel rails, and the middle portion of the substrate is suspended. The dispensing stage is raised to support the substrate through the gap. The substrate is lifted and disengaged from contact with the pair of parallel rails. The substrate is fixed with a retention member above the substrate to facilitate positioning.

According to an embodiment of the invention, the anti-stain device comprises an isolation paper storage and delivery unit coupled to one side of the dispensing stage, and a pile of isolation paper is placed in the isolation paper storage and delivery unit. The isolation paper is delivered to the upper surface of the dispensing storage through a roller and a guiding mechanism. A transition connection platform is disposed between the isolation paper storage and delivery unit and the dispensing storage, so that the isolation paper is smoothly fed to the upper surface of the dispensing storage without jamming. The anti-stain device further comprises a displacement unit for removing the isolation paper from the upper surface of the dispensing storage.

According to another embodiment of the present invention, the anti-stain device comprises a first roller, on which a roll of isolation paper is installed, and a second roller connected to one end of the roll of isolation paper. The first roller and the second roller are operated at the same rotational speed and the same rotational direction, so that the isolation paper is rolled in a predetermined direction. When dispensing process is performed, the dispensing storage first lifts the isolation paper between the first roller and the second roller, and then lifts the substrate. Since the upper surface of the dispensing storage is covered by the isolation paper, the anti-stain effect can be achieved.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A glue dispensing apparatus, comprising:
a conveying device;
at least one substrate moved along a predetermined direction by the conveying device;
a dispensing stage located under the conveying device; and
an anti-stain device coupled to the dispensing stage for providing isolation paper between the substrate and the dispensing stage.

2. The glue dispensing apparatus according to claim 1, wherein the substrate is a leadframe-type substrate.

3. The glue dispensing apparatus according to claim 2, wherein the substrate comprises a die pad, a die mounted on the die pad, leads, and bonding wires for connecting the leads to the die.

4. The glue dispensing apparatus according to claim 3, wherein die pad comprises a recessed structure.

5. The glue dispensing apparatus according to claim 3, wherein the die pad comprises a roughened surface.

6. The glue dispensing apparatus according to claim 4 further comprising a glue dispensing nozzle positioned above the conveying device for applying a fluid glue material into the recessed structure such that the fluid glue material covers a portion of each of the bonding wires.

7. The glue dispensing apparatus according to claim 1, wherein the conveying device comprises a pair of parallel rails with a gap between the two parallel rails, so that only opposite side edges of the substrate are in direct contact with the pair of parallel rails, and a middle portion of the substrate is suspended.

8. The glue dispensing apparatus according to claim 7, wherein the dispensing stage is raised to support the substrate through the gap, and the substrate is lifted and disengaged from contact with the pair of parallel rails, wherein the substrate is fixed with a retention member above the substrate to facilitate positioning.

9. The glue dispensing apparatus according to claim 1, wherein the anti-stain device comprises an isolation paper storage and delivery unit coupled to one side of the dispensing stage, and the isolation paper is placed in the isolation paper storage and delivery unit, wherein the isolation paper is delivered to an upper surface of the dispensing storage through a roller and a guiding mechanism.

10. The glue dispensing apparatus according to claim 9, wherein a transition connection platform is disposed between the isolation paper storage and delivery unit and the dispensing storage, so that the isolation paper is smoothly fed to the upper surface of the dispensing storage without jamming.

11. The glue dispensing apparatus according to claim 9, wherein the anti-stain device further comprises a displacement unit for removing the isolation paper from the upper surface of the dispensing storage.

12. The glue dispensing apparatus according to claim 1, wherein the isolation paper is a dust-free paper.

13. The glue dispensing apparatus according to claim 1, wherein the dispensing stage comprises a plurality of vacuum holes.

14. The glue dispensing apparatus according to claim 1, wherein the anti-stain device comprises a first roller, on which a roll of isolation paper is installed, and a second roller connected to one end of the roll of isolation paper.

15. The glue dispensing apparatus according to claim 14, wherein the first roller and the second roller are operated at the same rotational speed and the same rotational direction, so that the isolation paper is rolled in a predetermined direction.
